(19) United States
(12) Patent Application Publication
(10) Pub. No.: US 2026/0271801 A1
(43) Pub. Date: Sep. 10, 2026

(54) SIGNAL PIN, ELECTRONIC DEVICE, AND METHOD OF ASSEMBLING AN ELECTRONIC DEVICE

(71) Applicants: NEXPERIA TECHNOLOGY (SHANGHAI) LTD., Shanghai (CN); NEXPERIA B.V., Nijmegen (NL)

(72) Inventors: Wei GONG, Stockport (GB); Jürgen Hogerl, Munich (DE); Ziliang Shi, Shanghai (CN); Zhao Zhang, Shanghai (CN); Song Cui, Wuxi (CN)

(73) Assignees: NEXPERIA TECHNOLOGY (SHANGHAI) LTD., Shanghai (CN); NEXPERIA B.V., Nijmegen (CN)

(21) Appl. No.: 19/660,092

(22) Filed: Apr. 27, 2026

Related U.S. Application Data
(63) Continuation of application No. PCT/CN2023/129080, filed on Nov. 1, 2023.

(51) Int. Cl. H10W 90/00

(52) U.S. Cl. CPC H10W 90/701

(57) ABSTRACT

The present disclosure relates to a pin used for a connection of an electronic device, such electronic device with the pin and the method of assembling such electronic device. The signal pin, which is suitable to be placed in a slot, includes a metal pin having a first end, a second end and a side surface, and a metal ribbon having a first end and a second end. The first end of the metal ribbon and the first end of the metal pin and/or the side surface of the metal pin form a galvanic connection.

### CROSS-REFERENCE TO RELATED APPLICATIONS

This application is a continuation of PCT/CN2023/129080 filed on Nov. 1, 2023, the contents of which are incorporated by reference herein in their entirety.

### BACKGROUND

### 1. Field of the Disclosure

The present disclosure relates to a pin used for a connection of an electronic device. The present disclosure also relates to such electronic device with the pin as well as a method of assembling such electronic device.

### 2. Description of the Related Art

Frame based power modules for wide band semiconductors in various applications, but with strong focus on automotive applications. Usually, modules for automotive application do have ultrasonic welded power terminals and is suggested to use this technology also for the signal pins due to cost and reliability.

Usually frame based power modules have solderable press fit contacts. Latest data have shown that reliability of those contacts (e.g. during temperature cycling and vibration test) is not sufficient so that alternatives are under consideration. Infineon for example has proposed to laser weld the jackets of the press fit contacts to the substrate to enhance reliability.

In the known electronic devices signal pins, in one example, be embedded in the housing such that only pins and solder pads of said pins are available. The pads are, in this case, a bended and flattened part of the pin. Said pin embedded in the housing cannot be removed without damaging the housing. In such example a galvanic connection between the pin and an electronic circuit is made usually by a bond wire, which has to be connected to the pin, in this example to the pad, and to the contacts on the electronic circuits. Such process requires that the connection be made in two points during this process.

In other known solution, a pin with a solder pad is being bended and a flattened part of the pin is placed in a slot of a housing. After the pin is placed in the slot an assembly process is performed similarly as described hereinbefore.

Accordingly, it is a goal of the present disclosure to provide an improved to the assembling process. A first goal of the invention is to reduce a number of connections made during the final assembly process. A second goal is to provide a solution which will be suitable to use with an ultrasonic soldering which may be used during the assembly process of an electronic device, especially in power modules where power connectors are already welded ultrasonically. A third goal is to enhanced reliability of an galvanic connection. A fourth goal is to reinforce the signal pin during reliability testing.

### SUMMARY

According to a first example of the disclosure, a signal pin is disclosed. The signal pin, suitable to be placed in a slot, comprises a metal pin comprising a first end, a second end and a side surface, and a metal ribbon comprising a first end and a second end. The first end of the metal ribbon and the first end of the metal pin and/or the side surface of the metal pin form a galvanic connection.

Preferably the metal ribbon has a thickness in the range of 100 μm to 1 mm, preferably in the range of 300 μm to 400 μm.

Preferably the metal ribbon is connected to the metal pin by either soldering, welding, gluing, by means of integrally bonding, or by means of a tube, wherein the first end of the metal ribbon forms a tube in which the metal pin is placed, wherein a hole in the tube is either a blind hole or a through hole.

Preferably the metal ribbon is made of copper.

Preferably the signal pin comprises a guiding shaft, preferably made of a non-conductive material, even more preferably made of plastic. The guiding shaft comprises an opening. At least the metal pin is placed inside the opening. Even more preferably the metal pin and the opening forms a press fit connection.

Preferably the guiding shaft is wider than the metal ribbon.

Preferably a cross-section of the guiding shaft, perpendicular to the metal pin, has a shape that prevents a rotation of the signal pin when placed in the slot. Even more preferably the cross-section of the guiding shaft has a shape of a rectangle, a square, a triangle or an ellipsis, and preferably the cross-section of the guiding shaft remains the same throughout the whole length of the guiding shaft.

Preferably the signal pin comprises at least one locking means configured to lock the signal pin in the slot. Such locking means are preferably configured as a thread, as grooves or as a locking mechanism, even more preferably the locking mechanism is formed as a latch or as a protrusion.

Preferably the metal ribbon is rigid.

Preferably the metal ribbon is pre-bended.

According to a second example of the disclosure, an electronic device is disclosed. The electronic device comprises a housing with at least one slot, an electronic circuit with at least one connection pad, and at least one signal pin. The at least one signal pin is placed in one slot such that there is one signal pin in one slot. A second end of a metal ribbon of each of the at least one signal pin is galvanically connected with the connection pad. Even more preferably each of the at least one signal pin is connected to only one connection pad.

Preferably the at least one slot forms a press fit connection with the signal pin.

Preferably the at least one slot comprises a side which is open.

According to a third example of the disclosure, a method of assembling an electronic device is disclosed. The method comprising steps of:
a. placing in a housing an electronic circuit with at least one connection pad,
b. inserting into at least one slot at least one signal pin such that a second end of at least one metal ribbon is placed on a connection pad,
c. connecting the second end of the at least one of metal ribbon with the at least one connection pad by means of an ultrasonic welding.

Preferably prior to step b) an additional step is performed during which the metal ribbon is bended.

### BRIEF DESCRIPTION OF THE DRAWINGS

The disclosure will now be discussed with reference to the drawings, which show in:

FIG. 1 one exemplary embodiment of a signal pin,

FIG. 2 an electronic device with housing comprising slots in which the signal pin, as shown in FIG. 1, are placed

FIGS. 3a-3e another examples of the signal pin,

FIG. 4 another variant of the signal pin from FIG. 3d.

### DETAILED DESCRIPTION

For a proper understanding of the disclosure, in the detailed description below corresponding elements or parts of the disclosure will be denoted with identical reference numerals in the drawings.

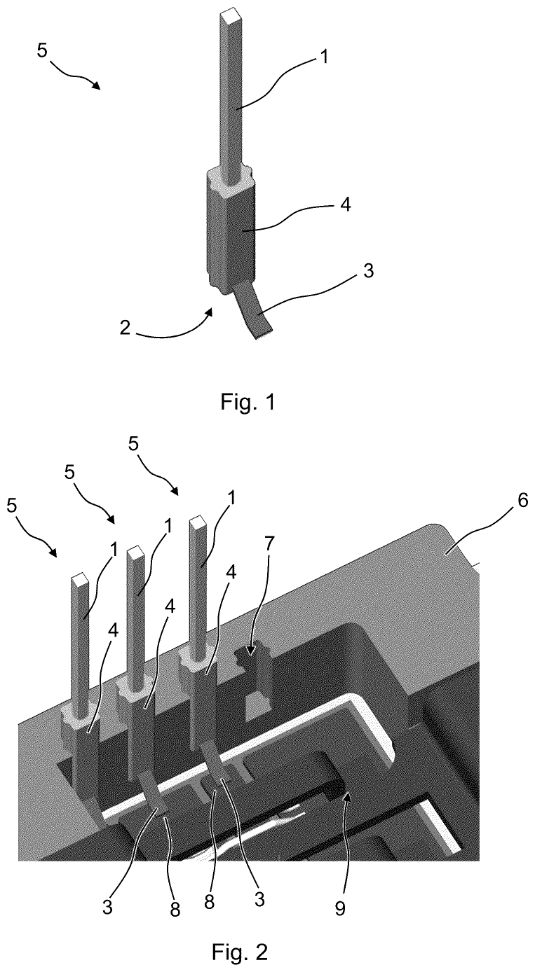

In FIG. 1 a signal pin, suitable to be placed in a slot, is shown. Such signal pin comprising a metal pin 1 comprising a first end 1a, a second end 1b and a side surface 1c, and a metal ribbon 3 comprising a first end 3a and a second end 3b. The first end 3a of the metal ribbon 3 and the first end 1a of the metal pin 1 and/or to the side surface 1c of the metal pin 1 forms a galvanic connection 2. In this particular example also a guiding shaft 4 is present.

The metal pin 1 has usually a height up to 50 mm, preferably in the range of 10 mm to 15 mm. It may have any shape of a cross-section such as a square or a circle however the person skilled in the art will know that any shape may be used. A circumscribed circle on the cross-section of the metal pin 1 will have a radius preferably within a range of 0.3 mm up to 1 mm, even more preferably within a range of 0.35 mm to 0.5 mm.

The metal ribbon 3 is preferably made of a copper. The metal ribbon 3 is also preferably rigid which allows for easier assembly due to a fact that only the metal pin 1 needs to be guided and the metal ribbon 3 will keep its position with respect to the metal pin 1. It should be noted that the metal ribbon 3 is a thin strip of a metal sheet. The metal ribbon 3 preferably has a thickness of 100 μm to 1 mm, preferably 300 μm to 400 μm and it has length sufficient to connect the pin 1 with a desired pad. In such a case the length of the metal ribbon 3 will have typically a rang from few millimeters to few centimeters—in an exemplary embodiment it may have a length up to 50 mm, preferably the length is in a range of 5 to 15 mm. The width of the metal ribbon is up to 10 mm, preferably it is within a range of 0.5-2 mm.

It should be also noted that the metal ribbon 3 provides a great benefit that it is easily deformable in one direction, that is perpendicular to a shorter side of the metal ribbon 3, and thus positioning is an easy task since side movements/rotation are controlled by rotating the signal pin 5 and the up/down movement do not have to be precises since the metal ribbon 3 will act as a spring and thus provide quite large margin of error in terms of vertical positioning. It should also be noted that the metal ribbon 3 may also be pre-bended prior to positioning in the slot 7 allows for greater application where the connection pad 8 is placed below the first end 3a of the metal ribbon.

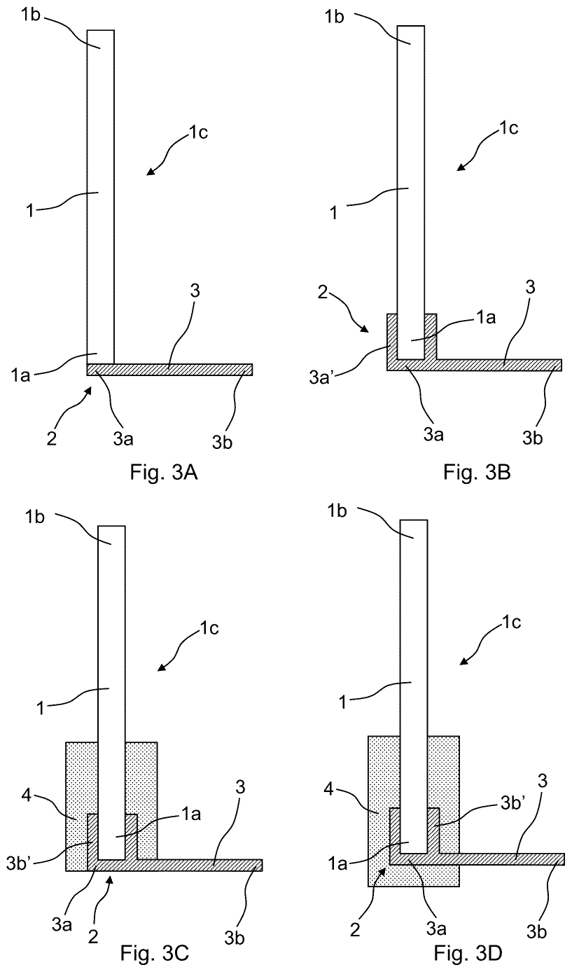

In FIG. 2 an electronic device is shown. Said electronic device comprises a housing 6 with at least one slot 8, an electronic circuit 9 with at least one connection pad 8, and at least one signal pin 5. Each of the at least one signal pin 5 is placed in one slot 8, such that there is one signal pin 5 in one slot 8, preferably the at least one slot 8 forms a press fit connection with the signal pin 5. A second end 3b of a metal ribbon 3 of each of the at least one signal pin 5 is galvanically connected with the connection pad 8, preferably each of the at least one signal pin 5 is connected to only one connection pad 8.

The electronic device, as shown in FIG. 2, is assembled by performing the following steps. Firstly, during a step a), an electronic circuit 9 with at least one connection pad 8 is placed in a housing. Next, during step b), at least one signal pin 5 is inserted into at least one slot 8 such that a second end 3b of at least one metal ribbon 3 is placed on a connection pad 8. Finally, during step c), the second end 3b of the at least one of metal ribbon 3 is ultrasonically welded with the at least one connection pad 8. It should be noted that preferably one side of the slot 8 is open so that, when the signal pin 5 is inserted into the slot 8, the metal ribbon 3 is not disturbed by the edge of the slot 8.

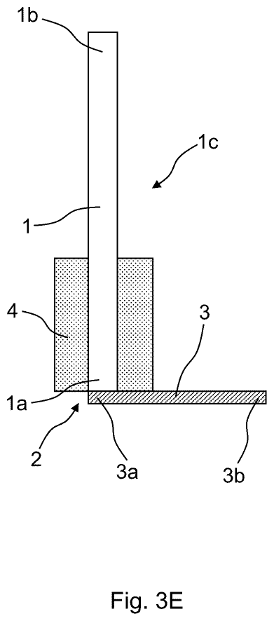

Additional examples of signal pins 5 are presented on FIGS. 3a-3e. Throughout all FIGS. 3a-3e a galvanic connection 2 is made by connecting a first end 3a of the metal ribbon 3 with a first end 1a of the metal pin 1 and/or side surface 1c of the metal pin 1. A second end 1b of the metal pin 1 is used to connect an electronic device with other elements or circuits. A second end 3b of the metal ribbon 3 is used to connect the signal pin 5 with a connection pad 8 by means of the ultrasonic welding.

A simple example of the signal pin 5 is presented in FIG. 3a. The signal pin comprises only the metal pin 1 and the metal ribbon 3. The galvanic connection 2 is achieved by means of soldering, welding, gluing or by means of integrally bonding the first end 3a of the metal ribbon 3 with the first end 1a of the metal pin 1. It is also possible that the first end 3a of the metal ribbon 3 is also, or instead of, connected to the side surface 1c of the metal pin 1.

In FIG. 3b a similar concept to the signal pin 5 from FIG. 3a is shown. In this figure the galvanic connection 2 is made with a tube 3a′ being a part of the metal ribbon 3, more precisely the tube 3a′ is connected to the first end 3a of the metal ribbon 3 and the metal pin 1 is inserted into a hole of the tube 3a'. It should be noted that the hole in the tube 3a′ is either a blind hole or a through hole. Such tube 3a′ may have the hole which, by itself, will form a tight fit connection with the metal pin 1 or the tube 3a′ may be squeezed while the metal pin 1 is inside the hole.

In FIG. 3c the signal pin 5 from FIG. 3b is shown with a difference that in this example the signal pin 5 comprises a guiding shaft 4. The guiding shaft 4 is preferably made of a non-conductive material such as plastic. The guiding shaft 4 comprising an opening, and the metal pin 1 and the tube 3a′ are placed inside the opening. Preferably the metal pin 1 and the opening forms a press fit connection. When the pin 1 is inserted into the tube 3a', the tube 3a′ deforms since the pin 1 is square in diameter. The deformation forms a tight fit locking the pin 1 into the guiding shaft 4. The signal pin 5 according to this example is designed for a single use-it is not the intention that the pin 1 is removed from the guiding shaft 4.

In FIG. 3d a similar signal pin 5 is presented as in FIG. 3c with a difference that the guiding shaft 4 surrounds the whole tube 3a′.

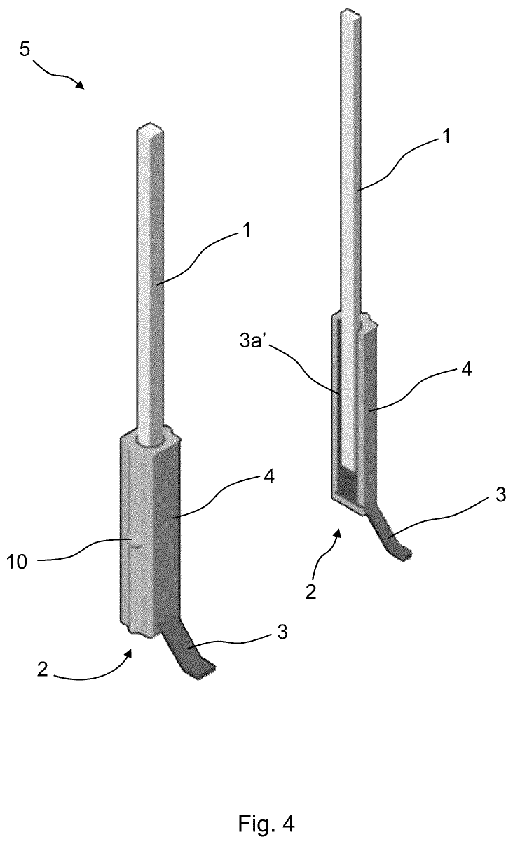

In FIG. 4 an additional version is shown in which the tube 3a′ goes through the whole opening of the guiding shaft 4.

In FIG. 3e the signal pin 5, as shown in FIG. 3a, also comprises a guiding shaft 4, similarly as in FIG. 3c.

It should be noted that the guiding shaft 4 is preferably wider than the metal ribbon 3. Such solution would allow an easier assembling since the metal ribbon 3 is protected by the guiding shaft 4 and a risk that the metal ribbon 3 will be pulled off accidentally is lowered.

The guiding shaft 4 also preferably has a cross-section perpendicular to the metal pin 1 which has a shape that prevents a rotation of the signal pin 5 when placed in the slot 8. Such shape of the cross-section, for example, is a rectangle, a square, a triangle or an ellipsis, but the person skilled in the art will know other shapes which will be suitable. Preferably the cross-section of the guiding shaft 4 remains the same throughout the whole length of the guiding shaft 4 thus allowing for an easier manufacturing due to the slot 8 being easier to manufacture and that the assembling process will be easier. It should be noted that both features, namely a shape of the cross-section and the shape remaining the same throughout the whole length of the guiding shaft 4, are independent features, however both of these features may be present in one exemplary embodiment of the signal pin 5.

It should be noted that the signal pin 5 can comprise locking means configured to lock the signal pin 5 in the slot 8. Such locking means are, for example, a thread, grooves or a locking mechanism. An example of such locking mechanism is a latch or a protrusion 10, as shown on FIG. 4, which may be placed such that the protrusion 10 is placed in a corresponding socket in the housing 6.

The use of the signal pin 5, as described herein before provides a solution to all mentioned problems in the prior art. The signal pin 5, where the metal ribbon 3 is already connected to the metal pin 1, reduces a number of connections made during the final assembly process. The presented solution is suitable to use with ultrasonic welding and thus all manufacturing processes, in which the ultrasonic welding is used, may also be used to connect the signal pins 5 and thus reduce the number of assembling processes, machines, and stations in a factory which will reduce time, space needed and final cost of the whole process. The metal ribbon 3, welded to the connection pad 8, provides a reliable galvanic connection. The signal pin 5, especially with the guiding shaft 4 and the locking means such as a protrusion 10, provides a secure connection with the housing 6.

### LIST OF REFERENCE NUMERALS USED

1 metal pin
1a first end of the metal pin
1b second end of the metal pin
1c side surface of the metal pin
2 galvanic connection
3 metal ribbon
3a first end of the metal ribbon
3b second end of the metal ribbon
3a′ tube
4 guiding shaft
5 signal pin
6 housing
7 slot
8 connection pad
9 electronic circuit
10 protrusion

1. A signal pin, suitable to be placed in a slot, comprising
a metal pin comprising a first end, a second end and a side surface; and
a metal ribbon comprising a first end and a second end,
wherein the first end of the metal ribbon and the first end of the metal pin and/or to the side surface of the metal pin forms a galvanic connection.

2. The signal pin according to claim 1, wherein the metal ribbon has a thickness of 100 μm to 1 mm.

3. The signal pin according to claim 1, wherein the metal ribbon is connected to the metal pin by either
soldering,
welding,
gluing,
integrally bonding, or
by a tube, wherein the first end of the metal ribbon forms a tube in which the metal pin is placed, and wherein the tube has a hole that is either a blind hole or a through hole.

4. The signal pin according to claim 1, wherein the metal ribbon is made of a copper.

5. The signal pin according to claim 1, wherein comprising a guiding shaft made of a non-conductive material, wherein the guiding shaft comprises an opening, wherein at least the metal pin is placed inside the opening, and wherein the metal pin and the opening form a press fit connection.

6. The signal pin according to claim 5, wherein the guiding shaft is wider than the metal ribbon.

7. The signal pin according to claim 5, wherein the guiding shaft has a cross section, perpendicular to the metal pin, and has a shape that is unable to rotate the signal pin when placed in the slot, wherein the cross-section of the guiding shaft has a shape selected from the group consisting of a rectangle, square, triangle, and ellipsis, and wherein the cross-section of the guiding shaft remains the same throughout the whole length of the guiding shaft.

8. The signal pin according to claim 1, further comprising at least one locking means configured to lock the signal pin in the slot, wherein the locking means are a thread, grooves or a locking mechanism, and wherein the locking mechanism is a latch or a protrusion.

9. The signal pin according to claim 1, wherein the metal ribbon is rigid.

10. The signal pin according to claim 1, wherein the metal ribbon is bended.

11. An electronic device comprising
a housing with at least one slot;
an electronic circuit with at least one connection pad; and
at least one signal pin according to claim 1,
wherein each of the at least one signal pin is placed in one slot so that there is one signal pin in one slot,
wherein each of the at least one signal pin have a metal ribbon with a second end that is galvanically connected with the connection pad, and wherein each of the at least one signal pin is connected to only one connection pad.

12. The electronic device according to claim 11, wherein the at least one slot forms a press fit connection with the signal pin.

13. The electronic device according to claim 11, wherein the at least one slot comprises a side which is open.

14. The electronic device according to claim 12, wherein the at least one slot comprises a side which is open.

15. A method of assembling an electronic device according to claim 11, comprising steps of:
a) placing in a housing an electronic circuit with at least one connection pad,
b) inserting into at least one slot at least one signal pin so that a second end of at least one metal ribbon is placed on a connection pad,
c) connecting the second end of the at least one of metal ribbon with the at least one connection pad by ultrasonic welding.

16. A method of assembling an electronic device according to claim 11, comprising steps of:
a) placing in a housing an electronic circuit with at least one connection pad;
b) inserting into at least one slot at least one signal pin so that a second end of at least one metal ribbon is placed on a connection pad; and
c) connecting the second end of the at least one of metal ribbon with the at least one connection pad by ultrasonic welding.

17. A method of assembling an electronic device according to claim 11, comprising steps of:
a) placing in a housing an electronic circuit with at least one connection pad;
b) inserting into at least one slot at least one signal pin so that a second end of at least one metal ribbon is placed on a connection pad; and
c) connecting the second end of the at least one of metal ribbon with the at least one connection pad by ultrasonic welding.

18. The method according to claim 15, wherein prior to step b) an additional step is performed during which the metal ribbon is bended.
